(19) United States
(12) Patent Application Publication
(10) Pub. No.: US 2015/0108570 A1
(43) Pub. Date: Apr. 23, 2015

(54) SEMICONDUCTOR DEVICE

(71) Applicant: Renesas Electronics Corporation, Kawasaki-shi (JP)

(72) Inventors: Naoyoshi KAWAHARA, Kanagawa (JP); Nobuhiro TANABE, Kanagawa (JP)

(73) Assignee: Renesas Electronics Corporation, Kawasaki-shi (JP)

(21) Appl. No.: 14/511,885

(22) Filed: Oct. 10, 2014

(30) Foreign Application Priority Data
Oct. 21, 2013 (JP) 2013-218034

(51) Int. Cl. H01L 29/423; H01L 27/088; H01L 29/78

(52) U.S. Cl. CPC H01L 29/4236; H01L 29/7827; H01L 29/4238; H01L 27/088
USPC 257/334; 257/330

(57) ABSTRACT

A transistor having a trench gate is controlled such that values settable as on current of the transistor are not discrete. A first transistor includes a plurality of first trenches, a first gate insulating film, and a first gate electrode. The first trenches are provided on a substrate, and are arranged side by side in a plan view. The first gate insulating film is provided on at least a side face of each of the first trenches, and over each of substrate regions located between the first trenches. The first gate electrode is embedded in each of the first trenches, and is provided over each of regions of the first gate insulating film located between the first trenches. At least one of the first trenches is formed as a circular trench in a plan view.

### CROSS-REFERENCE TO RELATED APPLICATIONS

The disclosure of Japanese Patent Application No. 2013-218034 filed on Oct. 21, 2013 including the specification, drawings and abstract is incorporated herein by reference in its entirety.

### BACKGROUND

The present invention relates to a semiconductor device, and is, for example, a technology applicable to a semiconductor device having a gate electrode embedded in trenches on a substrate.

Technologies for achieving a finer transistor include a technique where a gate electrode is embedded in trenches on a substrate (a trench gate). For example, Japanese Unexamined Patent Application Publication No. Hei 11(1999)-103058 describes that a plurality of trenches arranged in a first direction are formed on a substrate, and a gate electrode is formed in each of the trenches and over each of substrate regions located between the trenches. Japanese Unexamined Patent Application Publication No. Hei 11(1999)-103058 further describes that on resistance of the transistor increases with an increase in trench-to-trench space.

### SUMMARY

Gate width of a transistor is one of important factors determining on current of the transistor. In a transistor having the trench gate, however, since a value of the gate width significantly varies depending on the number of trenches, values settable as the gate width are discrete. Hence, values settable as the on current of the transistor may also be discrete. Other issues and novel features will be clarified from the description of this specification and the accompanying drawings.

According to an embodiment of the present invention, there is provided a semiconductor device that includes a substrate and a first transistor. The first transistor includes a plurality of first trenches, a first gate insulating film, and a first gate electrode. The first trenches are provided on the substrate, and are arranged side by side in a plan view. The first gate insulating film is provided on at least a side face of each of the first trenches, and over each of substrate regions located between the first trenches. The first gate electrode is embedded in each of the first trenches, and is provided over each of regions of the first gate insulating film located between the first trenches. At least one of the first trenches is formed as a circular trench in a plan view. The circular trench has a visible outline 50% or more of which is formed of a curved line. The curved line is outwardly convex.

According to the above-described embodiment of the invention, a transistor having a trench gate can be controlled such that values settable as on current of the transistor are not discrete.

### BRIEF DESCRIPTION OF THE DRAWINGS

FIG. 1 is a plan view illustrating a configuration of a semiconductor device according to a first embodiment.

FIG. 2 is a plan view illustrating the semiconductor device of FIG. 1 in which a portion of a first gate electrode located above first trenches is omitted.

FIG. 3 is a sectional view along A-A′ in FIG. 1.

FIG. 4 is a sectional view along B-B′ in FIG. 1.

FIG. 5 illustrates a pattern provided in a reticule.

FIG. 6 is a graph illustrating a relationship between size of an auxiliary pattern and oblateness of a first trench in the case where a shape and size of a pattern are fixed.

FIG. 7 illustrates areal occupancy of a first transistor.

FIG. 8 illustrates a transistor according to a comparative example, and areal occupancy of the transistor.

FIG. 9 illustrates a configuration of a semiconductor device according to a second embodiment.

FIG. 10 is a plan view illustrating a configuration of a semiconductor device according to a third embodiment.

FIG. 11 illustrates a modification of the semiconductor device of FIG. 10.

FIG. 12 is a plan view illustrating a configuration of a semiconductor device according to a fourth embodiment.

FIG. 13 is a sectional view illustrating a configuration of a semiconductor device according to a fifth embodiment.

### DETAILED DESCRIPTION

Hereinafter, some embodiments are described with the accompanying drawings. In all the drawings, like components are designated by like numerals, and duplicated description is appropriately omitted.

### First Embodiment

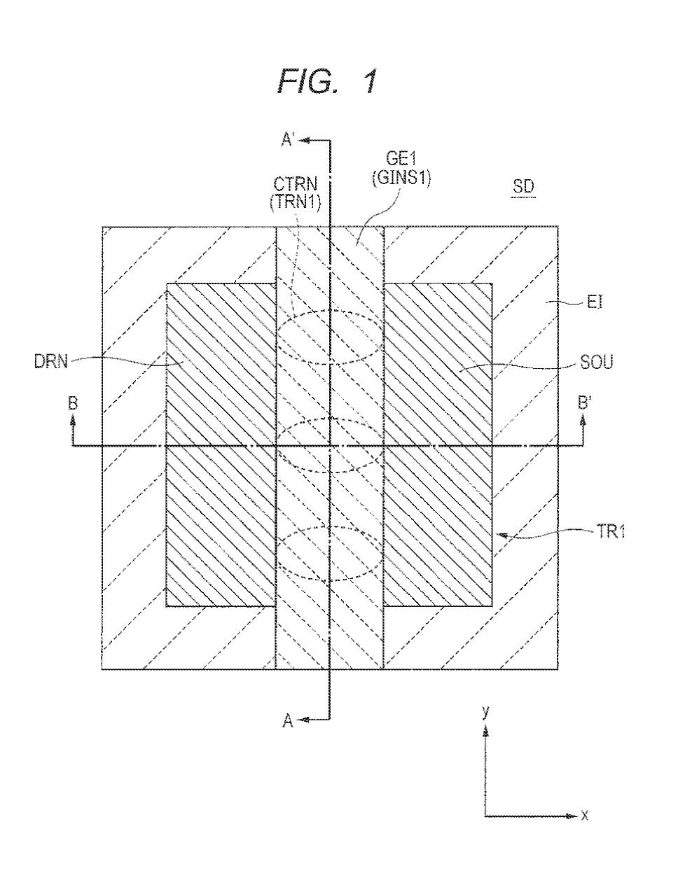

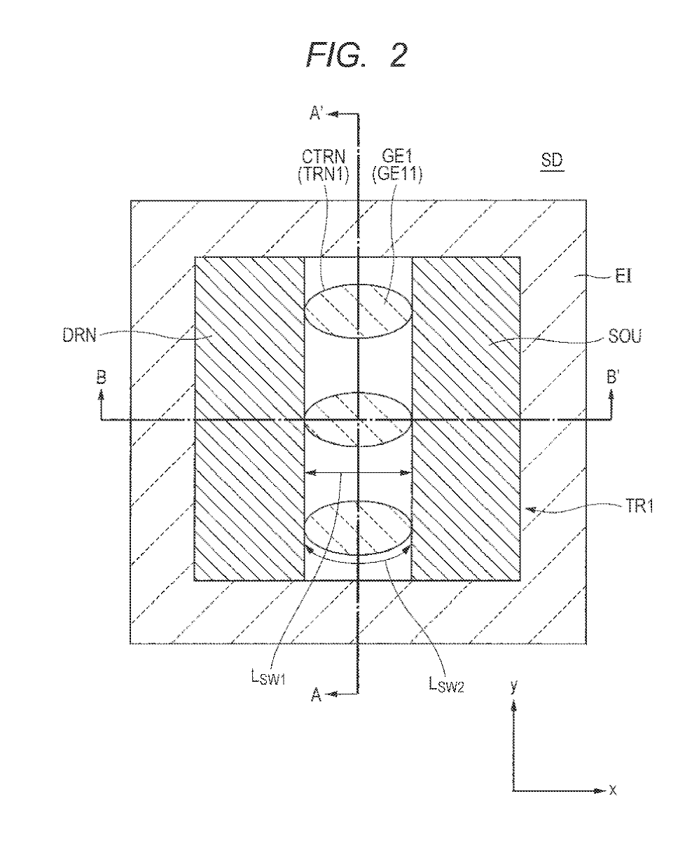

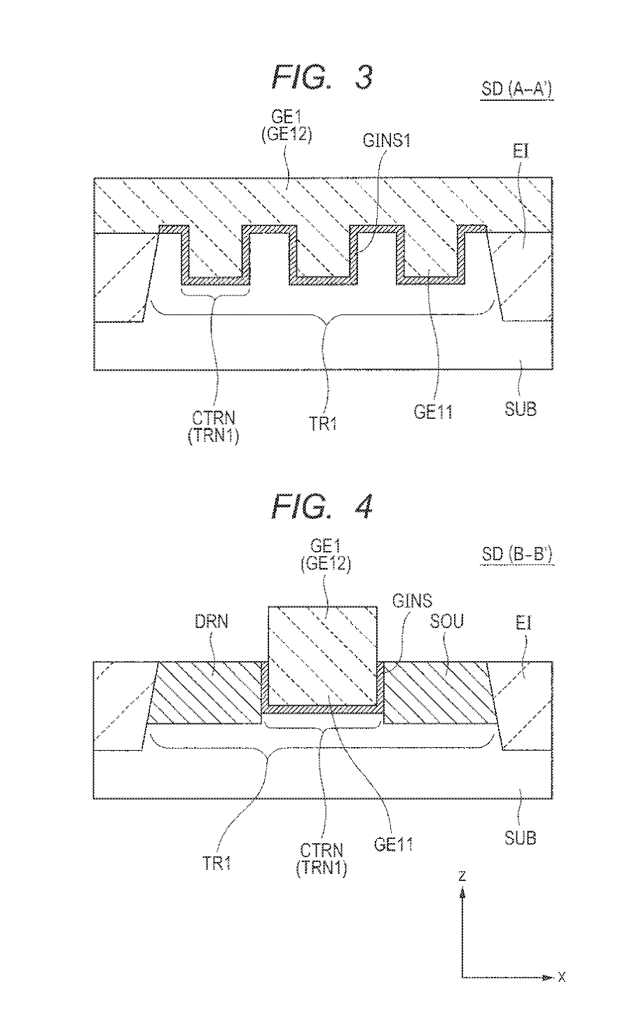

FIG. 1 is a plan view illustrating a configuration of a semiconductor device SD according to a first embodiment. FIG. 2 is a view illustrating the semiconductor device SD of FIG. 1 in which a portion of a first gate electrode GE1 located above first trenches TRN1 is omitted. FIG. 3 is a sectional view along A-A′ in FIG. 1. FIG. 4 is a sectional view along B-B′ in FIG. 1. The semiconductor device SD according to the first embodiment includes a substrate SUB and a first transistor TR1. The first transistor TR1 includes the plurality of first trenches TRN1, a first gate insulating film GINS1, and the first gate electrode GE1. The first trenches TRN1 are provided on the substrate SUB, and are arranged side by side in a plan view. The first gate insulating film GINS1 is provided on at least a side face of each of the first trenches TRN1, and over each of regions of the substrate SUB located between the first trenches TRN1. The first gate electrode GE1 is embedded in each of the first trenches TRN1, and is provided over each of regions of the first gate insulating film GINS1 located between the first trenches TRN1. At least one of the first trenches TRN1 is formed as a circular trench CTRN in a plan view. The circular trench CTRN has a visible outline 50% or more of which is formed of a curved line. The curved line is outwardly convex. The configuration is now described in detail.

The substrate SUB is a semiconductor substrate such as a silicon substrate, for example. An element separation film E1 is embedded in the substrate SUB. The element separation film E1 separates a region, in which the first transistor TR1 is provided, from other regions. Although the element separation film E1 is formed by, for example, a trench isolation process, it may be formed by a local oxidation of silicon (LOCOS) process.

The plurality of first trenches TRN1 are provided on the substrate SUB. The first trenches TRN1 are arranged side by side at equal spaces in a first direction (for example, a y direction in FIG. 1). At least one of the first trenches TRN1 is formed as a circular trench CTRN. In the exemplary case illustrated in FIGS. 1 to 4, any of the first trenches TRN1 is formed as the circular trench CTRN. The circular trench CTRN has an elliptical or circular shape.

In the exemplary case illustrated in FIGS. 1, 2, and 4, width (an x direction in FIGS. 1, 2, and 4) of a portion of the first gate electrode GE1 (a lower gate portion GE11) located in the first trench TRN1 is equal to width of a portion thereof (an upper gate portion GE12) located above the first trench TRN1. However, the width of the upper gate portion GE12 may be different from the width of the lower gate portion GE11.

The substrate SUB has a source SOU and a drain DRN formed therein. The source SOU and the drain DRN are each formed through introducing an impurity into the substrate SUB. In a plan view, the source SOU and the drain DRN are opposed to each other with the first gate electrode GE1 therebetween.

When width of a portion of the first gate electrode GE1 located over the semiconductor device SD is denoted as L_{sw1} (see FIG. 2), and when a half value of length of a visible outline of the first trench TRN1 is denoted as L_{sw2} (see FIG. 2), an equivalent circuit of the first transistor TR1 is represented by a transistor having a gate length of L_{sw1} coupled in parallel to a transistor having a gate length of L_{sw2}. When length of a curved line portion of a visible outline of the circular trench CTRN or oblateness of the circular trench CTRN is varied, on current of the first transistor TR1 is continuously varied. Consequently, as described below, it is possible to control such that values settable as on current of the transistor are not discrete.

An on current Ion of a MOS transistor is represented by Formula (1).

Iₒₙ=WμCₒₓ/L×{(Vg−Vt)Vd−Vd²/2} (1)

In the Formula (1), W is gate width, p is electron mobility, Cₒₓ is unit volume of a gate oxide film, and L is gate length. In addition, Vg is gate voltage, Vt is threshold voltage, and Vd is drain voltage.

If the circular trench CTRN is a true circle, L_{sw2} is about 1.57×L_{sw2}. The L_{sw2} may have an arbitrary value in a range of 1 to 1.57 times as large as the value of the L_{sw1} through adjusting oblateness of the circular trench CTRN. Hence, through adjusting the oblateness of the circular trench CTRN, it is possible to adjust Ion of a portion, which corresponds to a transistor having a gate length of L_{sw2}, of the first transistor TR1 within a range from 0.64 to 1 assuming that Ion is 1 at L=L_{sw1}.

In the exemplary case illustrated in FIGS. 1 to 4, the first gate insulating film GINS1 is also provided on a bottom of each first trench TRN1. In an alignment direction of the first trenches TRN1, a distance between a first trench TRN1, which is closest to the element separation film E1 among the first trenches TRN1, and the element separation film E1 is preferably half the distance between the two adjacent first trenches TRN1.

A method of manufacturing the first transistor TR1 is now described. First, the element separation film E1 is formed on the substrate SUB. Subsequently, the first trenches TRN1 are formed in the first transistor TR1. The first trenches TRN1 are formed in the following manner, for example.

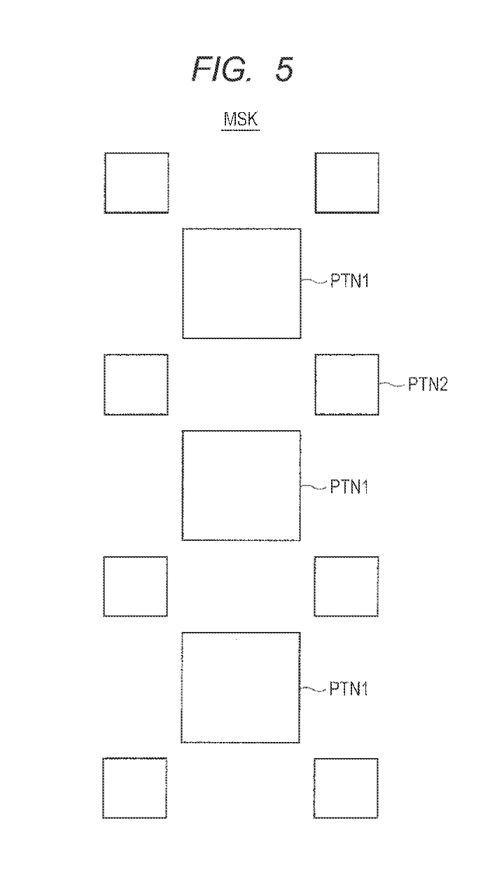

First, a hard mask film (for example, a stacked film of a SiO₂ film and a SiN film) over the substrate SUB and the element separation film E1. Subsequently, a resist film is formed over the hard mask film, and the resist film is exposed through a reticule MSK (described later with FIG. 5) and then developed. Consequently, an opening pattern is formed in the resist film. Subsequently, the hard mask film is etched with the opening pattern as a mask. Consequently, an opening pattern is formed in the hard mask film. Subsequently, the substrate SUB is etched with the hard mask film as a mask. Consequently, a plurality of first trenches TRN1 are formed.

Subsequently, the first gate insulating film GINS1 is formed on the substrate SUB. For example, the first gate insulating film GINS1 is formed by thermal oxidation of the substrate SUB. The first gate insulating film GINS1 may be formed by a deposition process such as a CVD process or a sputtering process.

Subsequently, a conductive film (for example, a polysilicon film) is formed in each first trench TRN1, over the substrate SUB, and over the element separation film E1. Subsequently, a mask pattern (for example, a resist pattern) is formed over the conductive film, and the conductive film is etched with the resist pattern as a mask. Consequently, the first gate electrode GE1 is formed. Subsequently, an impurity is ion-implanted into the substrate SUB with the first gate electrode GE1 and the element separation film E1 as a mask. Consequently, the source SOU and the drain DRN are formed.

FIG. 5 is a view illustrating a pattern of the reticule MSK. In the exemplary case illustrated in FIG. 5, the reticule MSK has patterns PTN1 for forming the first trenches TRN1, and auxiliary patterns PTN2 disposed around each of the patterns PTN1. Each of the pattern PTN1 and the auxiliary pattern PTN2 has a rectangular shape. The auxiliary pattern PTN2 is smaller than the pattern PTN1, and is disposed near each of four corners of the pattern PTN1. Adjusting size or a position of the pattern PTN2 makes it possible to adjust the oblateness of the first trench TRN1.

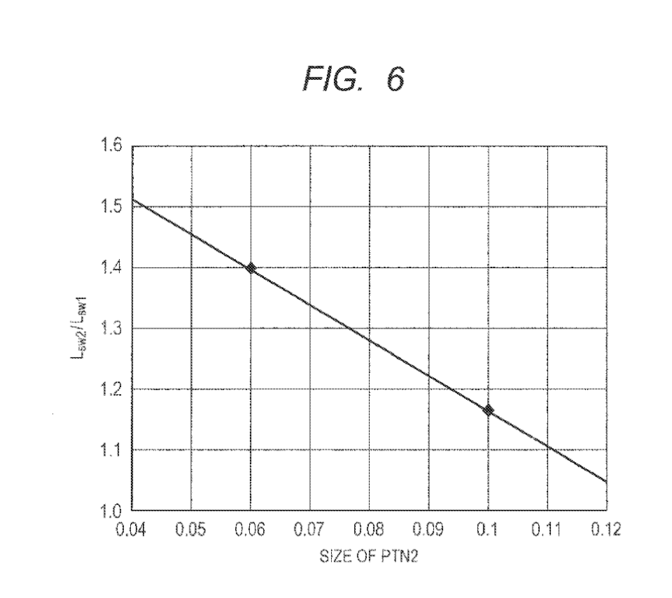

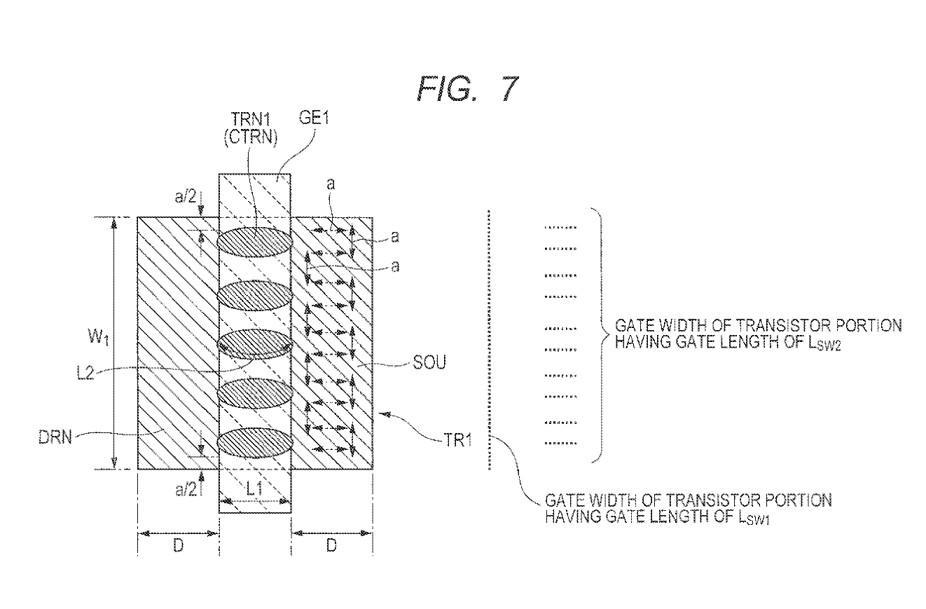

FIG. 6 illustrates a relationship between size of the auxiliary pattern PTN2 and the oblateness of the first trench TRN1 when the shape and the size of the pattern PTN1 are fixed. In FIG. 6, L_{sw2}/L_{sw1} (see FIG. 2) is used as an index indicating the oblateness. As the L_{sw2}/L_{sw1} is smaller, the oblateness is larger. FIG. 6 reveals that adjusting the size of the auxiliary pattern PTN2 makes it possible to adjust the oblateness of the first trench TRN1.

When the resist is a positive resist, the pattern PTN1 and the auxiliary pattern PTN2 each correspond to a reticule MSK portion having no light-shielding film thereon. Conversely, when the resist is a negative resist, the pattern PTN1 and the auxiliary pattern PTN2 each correspond to a reticule MSK portion having a light-shielding film thereon.

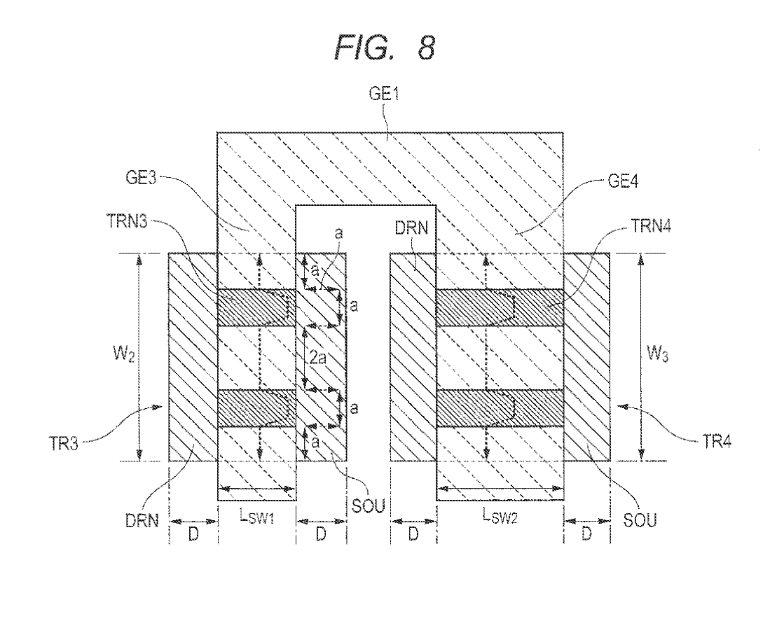

Areal occupancy of the first transistor TR1 is now described with FIGS. 7 and 8. In FIGS. 7 and 8, each broken line having a width a extending in a lateral direction represents a portion extending in a depth direction of the gate width.

FIG. 7 illustrates the gate width of the transistor having the gate length of L_{sw1} and the gate width of the transistor having the gate length of L_{sw2} in the first embodiment. As illustrated in FIG. 7, when five circular trenches CTRN are arranged at a space a while each circular trench CTRN has a depth of a, and when a distance between each end circular trench CTRN and the element separation film E1 is a/2, the transistor having the gate length of L_{sw1} has a gate width of 10a, and the transistor having the gate length of L_{sw2} also has a gate width of 10a. In this case, the first transistor TR1 has a gate width W₁ of 10a. In addition, when each of the source SOU and the drain DRN has a width of D, the first transistor TR1 has an aerial occupancy S₁ of 10a×(2D+L_{sw1}).

FIG. 8 illustrates a case where a transistor TR3 having a gate length of L_{sw1} and a transistor TR4 having a gate length of L_{sw2} are separately provided, where the transistor TR3 has a gate width W₂ of 10a and the transistor TR4 also has a gate width W₃ of 10a. In this case, the transistor has a gate width W₂ of 6a. Each of the transistors TR3 and TR4 has an aerial occupancy S₂ of 6a×(4D+L_{sw1}+L_{sw2}).

When D=0.15 μm, L_{sw1}=0.15 μm, and L_{sw2}=0.3 μm are given, S₂/S₁ is 0.714. In this way, the first transistor TR1 has a small aerial occupancy.

As described above, according to the first embodiment, the Ion of the first transistor TR1 can be continuously varied through adjusting the oblateness of the circular trench CTRN. In addition, the Ion can be varied without varying the aerial occupancy of the first transistor TR1. Furthermore, since the aerial occupancy of the first transistor TR1 is not increased, the first transistor TR1 can be made finer.

In addition, an appropriate number of circular trenches CTRN are introduced into a planar-type transistor (i.e., a transistor having no trench gate) that has been designed, making it possible to adjust on current of the transistor without varying aerial occupancy of the transistor. Consequently, any other configuration (for example, an interconnection layout) of the semiconductor device may not be modified in adjustment of the on current of the transistor.

### Second Embodiment

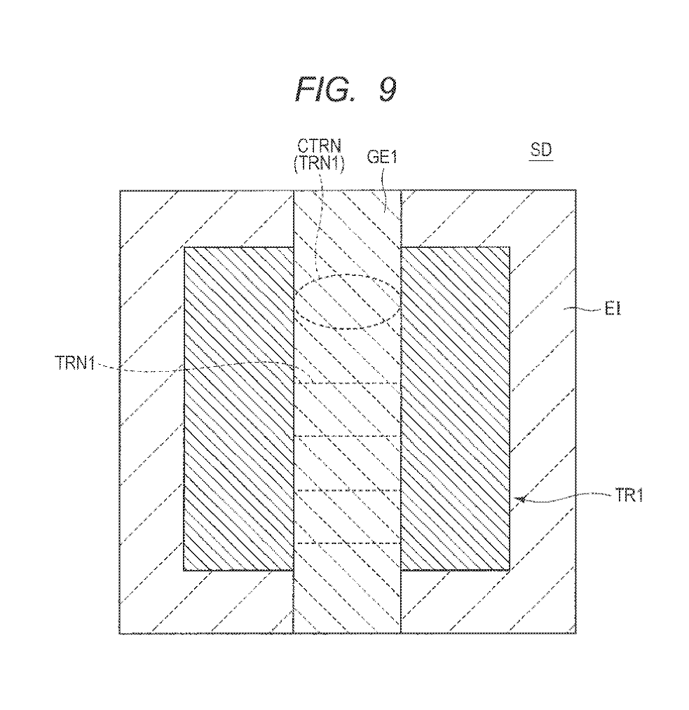

FIG. 9 illustrates a configuration of a semiconductor device SD according to a second embodiment. The semiconductor device SD according to the second embodiment has a configuration similar to that of the semiconductor device SD according to the first embodiment except that only part of the first transistor TR1 is formed as the circular trench CTRN.

The second embodiment also provides effects similar to those of the semiconductor device SD according to the first embodiment. In addition, not only the oblateness of the circular trench CTRN but also the number of the circular trenches CTRN (a proportion of the circular trenches CTRN in the first trenches TRN1) is varied, which further widens an adjustment range of Ion.

### Third Embodiment

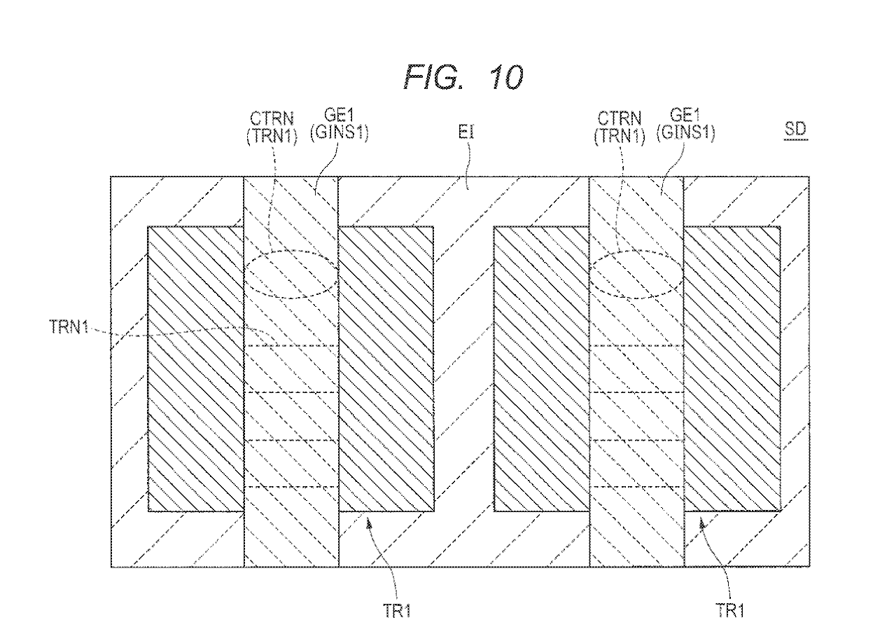

FIG. 10 is a plan view illustrating a configuration of a semiconductor device SD according to a third embodiment. The semiconductor device SD according to the third embodiment has a configuration similar to that of the semiconductor device SD according to the first or second embodiment except that a plurality of first transistors TR1 are provided. In FIG. 10, the respective first transistors TR1 have the same number of the circular trenches CTRN. As seen from comparison between the first transistors TR1, positions of the circular trenches CTRN are mutually equivalent.

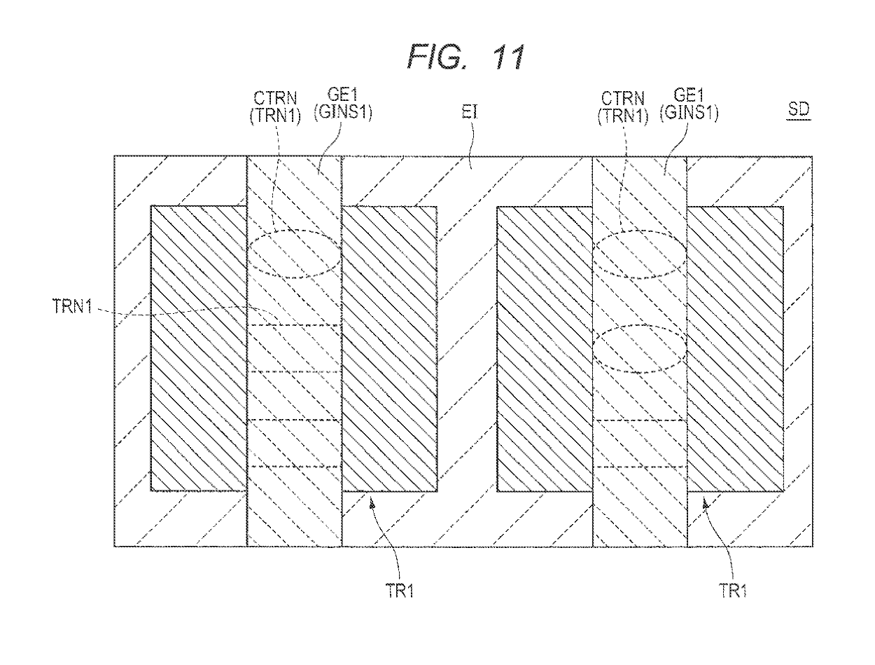

As illustrated in FIG. 11, the first transistors TR1 may have different numbers of the circular trenches CTRN from each other.

The third embodiment also provides effects similar to those of the semiconductor device SD according to the first or second embodiment. Moreover, on current Ion of each of planar-type transistors that have been designed can be independently varied without modifying a layout.

### Fourth Embodiment

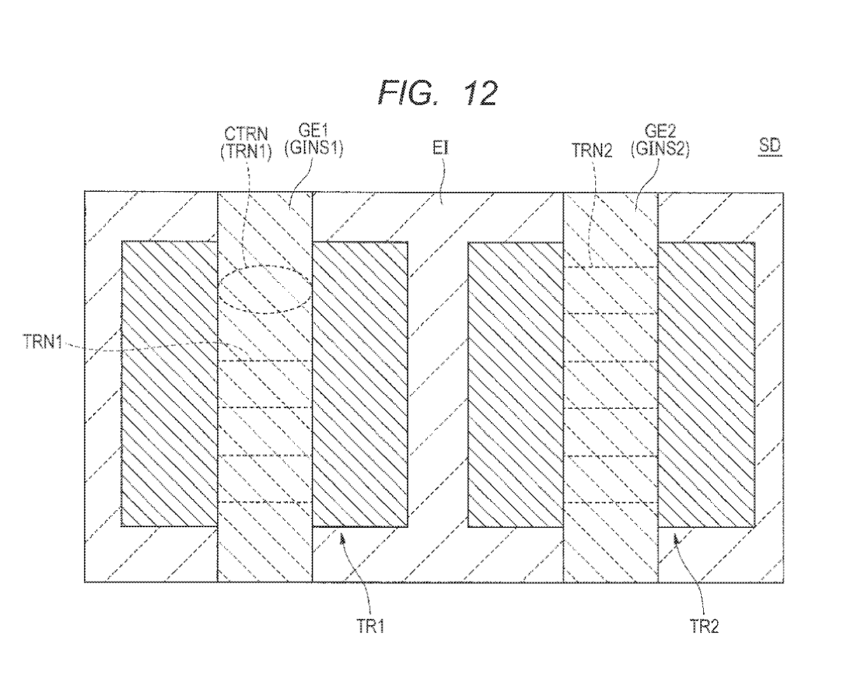

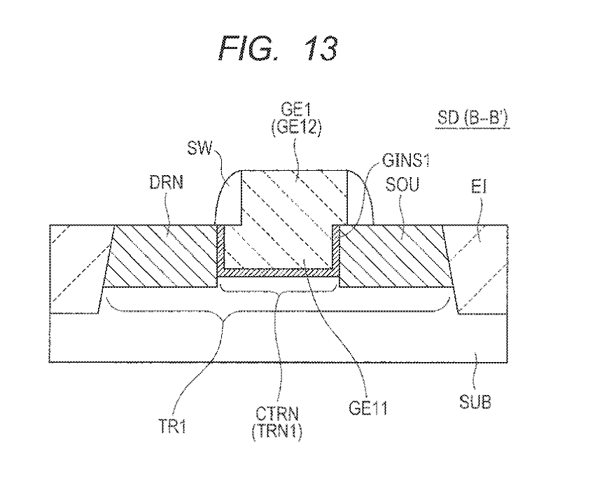

FIG. 12 is a plan view illustrating a configuration of a semiconductor device SD according to a fourth embodiment. The semiconductor device SD according to the fourth embodiment has a configuration similar to that of the semiconductor device SD according to one of the first to third embodiments except that a second transistor TR2 is provided in addition to the first transistor TR1. FIG. 12 illustrates a case where the first transistor TR1 is similar to that in the first embodiment.

The second transistor TR2 has a configuration similar to that of the first transistor TR1 except that no circular trench CTRN is provided. Specifically, the second transistor TR2 includes a plurality of second trenches TRN2, a second gate insulating film GINS2, and a second gate electrode GE2. The second trenches TRN2 are arranged side by side in a plan view. The second gate insulating film GINS2 is provided on at least a side face of each of the second trenches TRN2, and over each of regions of the substrate SUB located between the second trenches TRN2. The second gate insulating film GINS2 may also be provided on a bottom of each second trench TRN2. The second gate electrode GE2 is embedded in each of the second trenches TRN2, and is provided over each of regions of the second gate insulating film GINS2 located between the second trenches TRN2. Each of the second trenches TRN2 has a visible outline in which a proportion of a curved line portion is 20% or less in a plan view. The second trench TRN2 has a planar shape of a rectangle, for example. The respective second trenches TRN2 have the same shape in a plan view.

The fourth embodiment can also provide effects similar to those of one of the first to third embodiments. Moreover, only part of planar-type transistors that have been designed can be varied in on current Ion.

### Fifth Embodiment

FIG. 13 is a sectional view illustrating a configuration of a semiconductor device SD according to a fifth embodiment. FIG. 13 corresponds to FIG. 4 in the first embodiment. The semiconductor device SD according to the fifth embodiment has a configuration similar to that of the semiconductor device SD according to one of the first to fourth embodiments except for the following points.

A sidewall SW is provided on a side face of a portion of the first gate electrode GE1 (an upper gate portion GE12) located above the first trench TRN1. In addition, a portion of the first gate electrode GE1 (a lower gate portion GE11) located in the first trench TRN1 is offset from the upper gate portion GE12 in a plan view. A portion of the lower gate portion GE11, which is not covered with the upper gate portion GE12 due to such an offset, and part of the first gate insulating film GINS1, which is in contact with the portion, are covered with the sidewall SW.

The fifth embodiment also provides effects similar to those of one of the first to fourth embodiments.

Although the invention achieved by the inventors has been described in detail according to some embodiments hereinbefore, the invention should not be limited thereto, and it will be appreciated that various modifications or alterations thereof may be made within the scope without departing from the spirit of the invention.

What is claimed is:

1. A semiconductor device, comprising:
a substrate; and
a first transistor formed using the substrate,
the first transistor including:
a plurality of first trenches that are provided over the substrate, and are arranged side by side in a plan view;
a first gate insulating film that is provided over at least a side face of each of the first trenches, and over each of substrate regions located between the first trenches; and
a first gate electrode that is embedded in each of the first trenches, and is provided over each of regions of the first gate insulating film located between the first trenches,
wherein at least one of the first trenches is formed as a circular trench in a plan view, the circular trench having a visible outline 50% or more of which is formed of a curved line being outwardly convex.

2. The semiconductor device according to claim 1, wherein an external shape of the circular trench is an elliptical or circular shape in a plan view.

3. The semiconductor device according to claim 1, further comprising one or more first transistor in addition to the first transistor.

4. The semiconductor device according to claim 1, wherein the circular trench corresponds to part of the first trenches.

5. The semiconductor device according to claim 4, further comprising:
a second transistor formed using the substrate,
the second transistor including:
a plurality of second trenches that are provided over the substrate, and are arranged side by side in a plan view;
a second gate insulating film that is provided over at least a side face of each of the second trenches, and over each of regions of the substrate located between the second trenches; and
a second gate electrode that is embedded in each of the second trenches, and is provided over each of regions of the second gate insulating film located between the second trenches,
wherein each of the second trenches has a visible outline in which a proportion of a curved line portion is 20% or less in a plan view.
